(19) United States
(12) Patent Application Publication
(10) Pub. No.: US 2006/0145737 A1
(43) Pub. Date: Jul. 6, 2006

(54) Current-reuse-type frequency multiplier

(75) Inventors: Kazuya Yamamoto, Tokyo (JP); Fumimasa Kitabayashi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/300,281

(22) Filed: Dec. 15, 2005

(30) Foreign Application Priority Data
Jan. 6, 2005 (JP) 2005-001298

(51) Int. Cl. H03B 19/00

(52) U.S. Cl. 327/119

(57) ABSTRACT

A first differential input terminal is connected to one differential output terminal of a VCO, and a second differential input terminal is connected to the other differential output terminal of the VCO. RF signals in a complementary relationship with each other that are output from the VCO are input to the first and second differential input terminals as input signals. The gate of a first N-channel MOS transistor is connected to the first differential input terminal, and the gate of a second N-channel MOS transistors is connected to the second differential input terminal. The sources of the first and second N-channel MOS transistors are connected to a ground potential. The drains of the first and second N-channel MOS transistors are commonly connected to a node.

### BACKGROUND OF THE INVENTION

1. Field of the Invention

This invention relates to frequency multipliers, and more particularly to current-reuse-type frequency multipliers.

2. Description of the Background Art

A frequency multiplier has the function of converting an RF (Radio Frequency) signal output from a voltage control oscillator (hereafter referred to as a “VCO”) into a harmonic having a frequency which is an integral multiple of the fundamental frequency in a wireless system and the like. Recent technological progress toward finer CMOS has allowed the VCO and frequency multiplier to be integrated on an RF transceiver chip, resulting in numerous wireless LSIs being announced and put on the market. As CMOSs become finer, however, a gate breakdown voltage decreases, which requires an operating-voltage to decrease in each circuit block. For example, in a CMOS having a gate length of 0.18 μm, where an operation from a 1.8 V source is usually required, each circuit block needs to operate at a voltage of 1.8 V or less. However, in a Gilbert-Cell frequency multiplier that has conventionally been in widespread use, where a plurality of transistors are stacked vertically in three tiers between a power supply line and a ground line, sufficient output oscillation would be difficult to obtain at a power supply voltage of 1.8 V.

Japanese Patent Application Laid-Open No. 2003-332864 discloses a frequency doubler capable of operation at a power supply voltage of 1.8 V or less. This frequency doubler includes a first N-channel MOS transistor outputting a fundamental and a harmonic including a double wave on the basis of an RF signal input from a VCO, an eliminating circuit (which consists of an inductor and a capacitor) connected to the drain of the first N-channel MOS transistor and eliminating the fundamental output from the first N-channel MOS transistor, an extracting circuit (which consists of an inductor and a capacitor) connected to the drain of the first N-channel MOS transistor and extracting the double wave out of the harmonic output from the first N-channel MOS transistor, and a second N-channel MOS transistor connected to the drain of the first N-channel MOS transistor via the capacitor of the extracting circuit and amplifying and outputting the double wave extracted by the extracting circuit.

A direct current supplied from a power supply flows from the source of the second N-channel MOS transistor to the drain of the first N-channel MOS transistor via the inductor of the eliminating circuit. In other words, in the frequency doubler disclosed in Japanese Patent Application Laid-Open No. 2003-332864, the current flowing through the second N-channel MOS transistor is reused for operation of the first N-channel MOS transistor, thus reducing power consumption. Such frequency multiplier that reuses a current is hereafter referred to as a “current-reuse-type frequency multiplier” in the present specification.

When integrating the conventional frequency doubler disclosed in Japanese Patent Application Laid-Open No. 2003-332864 on an RF transceiver chip, the source of the first N-channel MOS transistor is connected to a source pad that is connected to a ground potential via ground wiring. Accordingly, as the RF signal increases in frequency, inductance dependent on the length of the ground wiring increases. That causes a source potential of the first N-channel MOS transistor to fluctuate with the value of current flowing through the ground wiring. In such ways, there has been a problem with this conventional frequency doubler in that the operation of the first N-channel MOS transistor is easily affected by the inductance of the ground wire.

### SUMMARY OF THE INVENTION

It is an object of this invention to provide a current-reuse-type frequency multiplier capable of reducing the effect of inductance of ground wiring.

In an aspect of the invention, a current-reuse-type frequency multiplier includes a harmonic-generating circuit, a harmonic-extracting circuit, an amplifying circuit, and a resistance element. The harmonic-generating circuit generates a harmonic including a plurality of frequency components on the basis of first and second input signals in a complementary relationship with each other. The harmonic-extracting circuit extracts a harmonic of a specific frequency component out of the harmonic generated by the harmonic-generating circuit. The amplifying circuit amplifies the harmonic extracted by the harmonic-extracting circuit to output the same. The resistance element controls a current flowing from the amplifying circuit into the harmonic-generating circuit. The harmonic-generating circuit includes a first transistor and a second transistor, the first transistor having a gate to which the first input signal is input, and the second transistor having a gate to which the second input signal is input.

The effect of inductance of ground wiring connected to the first and second transistors can be reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating the structure of a current-reuse-type frequency doubler according to a first preferred embodiment of this invention;

FIG. 2 is a circuit diagram illustrating the structure of a current-reuse-type frequency doubler according to a second preferred embodiment of this invention;

FIG. 3 is a top view schematically illustrating the structure of a differential inductor;

FIG. 4 is a circuit diagram illustrating the structure of a current-reuse-type frequency doubler according to a third preferred embodiment of this invention;

FIG. 5 is a circuit diagram illustrating the structure of a current-reuse-type frequency doubler according to a fourth preferred embodiment of this invention;

FIG. 6 is a circuit diagram illustrating the structure of a current-reuse-type frequency doubler according to a fifth preferred embodiment of this invention;

FIG. 7 is a circuit diagram illustrating the structure of a current-reuse-type frequency doubler according to a sixth preferred embodiment of this invention;

FIG. 8 is a circuit diagram illustrating the structure of a current-reuse-type frequency quadrupler according to a seventh preferred embodiment of this invention;

FIG. 9 is a circuit diagram illustrating the structure of a current-reuse-type frequency tripler according to an eighth preferred embodiment of this invention;

FIG. 10 is a circuit diagram illustrating the structure of a current-reuse-type frequency tripler according to a ninth preferred embodiment of this invention;

FIG. 11 is a circuit diagram illustrating the structure of a current-reuse-type frequency quadrupler according to a tenth preferred embodiment of this invention;

FIG. 12 is a circuit diagram illustrating the structure of a current-reuse-type frequency tripler according to an eleventh preferred embodiment of this invention; and

FIG. 13 is a circuit diagram illustrating the structure of a current-reuse-type frequency tripler according to a twelfth preferred embodiment of this invention.

### DESCRIPTION OF THE PREFERRED EMBODIMENTS

### First Preferred Embodiment

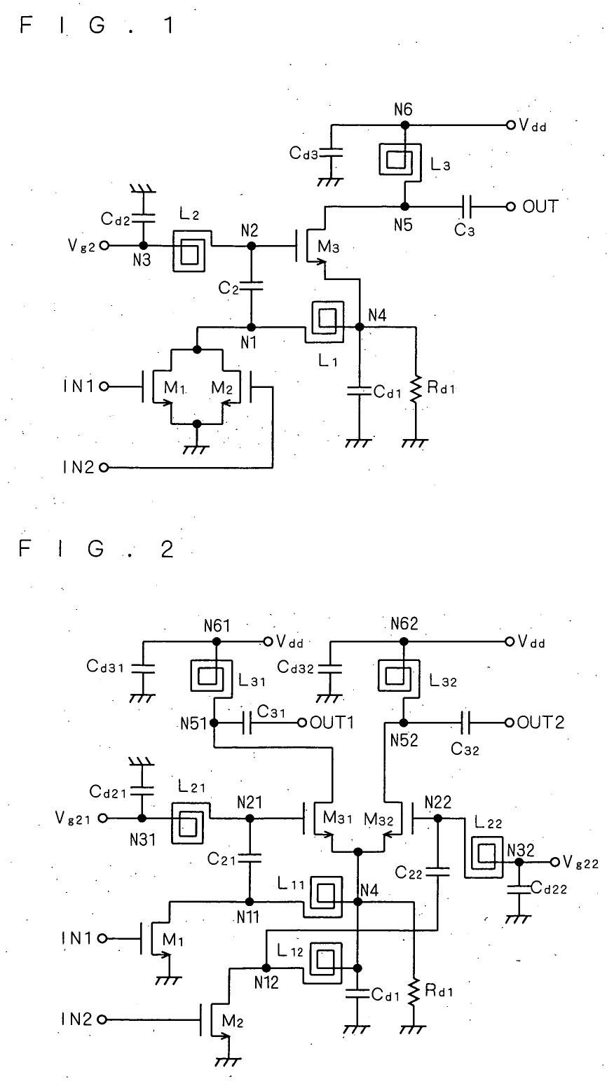

FIG. 1 is a circuit diagram illustrating the structure of a current-reuse-type frequency doubler according to a first preferred embodiment of this invention. As shown, this current-reuse-type frequency doubler includes differential input terminals IN1 and IN2, an output terminal OUT, N-channel MOS transistors M₁, M₂ and M₃, capacitors C_{d1}, C_{d2}, C_{d3}, C₂ and C₃, inductors L₁, L₂ and L₃, and a resistance element R_{d1}. The inductors L₁, L₂ and L₃ are formed of spiral inductors, for example.

Provided in the front stage of the current-reuse-type frequency doubler is a VCO (not shown) of differential operation having two differential output terminals. The differential input terminal IN1 is connected to one of the differential output terminals of the VCO, and the differential input terminal IN2 to the other differential output terminal of the VCO. RF signals in a complementary relationship with each other that are output from the VCO are input to the differential input terminals IN1 and IN2 as input signals.

The gate of the N-channel MOS transistor M₁ is connected to the differential input terminal IN1, and the gate of the N-channel MOS transistor M₂ to the differential input terminal IN2. The N-channel MOS transistors M₁ and M₂ each have a gate bias voltage being set near pinch-off voltage, which actually is set as a bias value between Class AB to Class B. The sources of the N-channel MOS transistors M, and M₂ are connected to a ground potential. More specifically, the sources of the N-channel MOS transistors M₁ and M₂ are commonly connected to a source pad (not shown) that is connected to a ground potential via ground wiring (not shown). The drains of the N-channel MOS transistors M₁ and M₂ are commonly connected to a node N1.

The capacitor C₂ is connected between the node N1 and a node N2. The inductor L₂ is connected between the node N2 and a node N3. The capacitor C_{d2} is connected between the node N3 and a ground potential. The inductor L1 is connected between the nodes N1 and N4. The capacitor C_{d1} is connected between the node N4 and a ground potential. The resistance element R_{d1} is connected between the node N4 and a ground potential.

The N-channel MOS transistor M₃ has a gate connected to the node N2, a source connected to the node N4, and a drain connected to a node N5. The capacitor C₃ is connected between the node N5 and the output terminal OUT. The inductor L₃ is connected between the node N5 and a node N6. The capacitor C_{d3} is connected between the node N6 and a ground potential.

A gate bias voltage V_{g2} of the N-channel MOS transistor M₃ is applied to the node N3. A power supply supplying a power supply voltage V_{dd} of 1.8 V or less is connected to the node N6.

The capacitors C_{d2} and C_{d3} act as decoupling capacitors. Namely, the capacitors C_{d2} and C_{d3} absorb noise (voltage fluctuations) on power supply wiring through the use of charge and discharge functions of capacitor.

Upon input of the RF signals in a complementary relationship with each other to the differential input terminals IN1 and IN2, a fundamental and an odd-ordered harmonic cancel each other out, and an even-ordered harmonic, primarily a double-wave, is output from the common drain of the N-channel MOS transistors M₁ and M₂. In other words, the N-channel MOS transistors M₁ and M₂ that are formed in a differential manner act as a harmonic-generating circuit for generating a harmonic including a plurality of frequency components on the basis of the RF signals in a complementary relationship with each other.

The capacitance of the capacitor C₂ and the inductance of the inductor L₂ are set to match a double-wave. Consequently, a double-wave is extracted out of the harmonic including a plurality of frequency components that appears at the node N1, and transmitted to the gate of the N-channel MOS transistor M₃. In other words, the capacitor C₂ and inductor L₂ act as a harmonic-extracting circuit for extracting a harmonic (double-wave in this case) of a specific frequency component out of the harmonic generated by the N-channel MOS transistors M₁ and M₂.

The capacitance of the capacitor C₃ and the inductance of the inductor L₃ are set to match a double-wave. Thus, the double-wave having been transmitted to the gate of the N-channel MOS transistor M₃ is amplified by the N-channel MOS transistor M₃, and then output from the output terminal OUT via the capacitor C₃.

When the respective RF signals input to the differential input terminals IN1 and IN2 are not entirely complementary to each other (that is, when an in-phase component is input to the differential input terminals IN1 and IN2), not only an even-ordered harmonic but a fundamental is output from the common drain of the N-channel MOS transistors M₁ and M₂. The capacitance of the capacitor C_{d1} and the inductance of the inductor L₁ are set to match a fundamental. Consequently, the fundamental that appears at the node N1 is shorted to a ground potential via the inductor L₁ and capacitor C_{d1}, to be eliminated. In other words, the capacitor C_{d1} and inductor L₁ act as a fundamental-eliminating circuit (fundamental trap) for eliminating the fundamental that appears at the node N1.

A direct current supplied from the power supply supplying the power supply voltage V_{dd} flows through the node N6, inductor L₃, node N5, N-channel MOS transistor M₃, node N4, inductor L1 and node N1 in this order, into the N-channel MOS transistors M₁ and M₂. In short, the current flowing through the N-channel MOS transistor M₃ is reused for operation of the N-channel MOS transistors M₁ and M₂, thus reducing power consumption.

In addition, part of the direct current flows from the node N4 to a ground potential via the resistance element R_{d1}, the amount of the current being controllable in accordance with the resistance value of the resistance element R_{d1}. Stated another way, the amount of current flowing from the N-channel MOS transistor M₃ into the N-channel MOS transistors M₁ and M₂ can be controlled by the resistance value of the resistance element R_{d1}. That allows an amplifying operation of the N-channel MOS transistor M₃ to be performed with stability even with a small operating current of the N-channel MOS transistors M₁ and M₂. That also prevents an amplifying operation of the N-channel MOS transistor M₃ from reaching saturation even when the output current of the N-channel MOS transistors M₁ and M₂ increase.

In the current-reuse-type frequency doubler according to the first preferred embodiment, a harmonic-generating circuit is formed in a differential manner by using the N-channel MOS transistors M₁ and M₂ to which the RF signals in a complementary relationship with each other are input. And as described above, the sources of the N-channel MOS transistors M₁ nd M₂ are commonly connected to the source pad that is connected to a ground potential via the ground wiring. Since the N-channel MOS transistors M₁ and M₂ operate in a complementary manner to each other (namely, the N-channel MOS transistor M₂ is under non-operating conditions while the N-channel MOS transistor M₁ is under operation conditions, and the N-channel MOS transistor M₂ is under operating conditions while the N-channel MOS transistor M₁ is under non-operation conditions), the source pad outwardly does not fluctuate in potential. Therefore, in the current-reuse-type frequency doubler according to the first preferred embodiment, the source pad does not fluctuate in potential when the RF signals increase in frequency to increase the inductance dependent on the length of the ground wiring. That allows the effect of the inductance of the ground wiring to be reduced or prevented in the operation of the N-channel MOS transistors M₁ and M₂.

Further, since the current-reuse-type frequency doubler according to the first preferred embodiment includes the two differential input terminals IN1 and IN2, the VCO of differential operation having two differential output terminals can be provided in the front stage of this doubler.

While the N-channel MOS transistors M₁, M₂ and M₃ are used in the current-reuse-type frequency doubler according to the first preferred embodiment, bipolar transistors or GaAs MES (Metal Semiconductor) FETs may alternatively be used instead of those N-channel MOS transistors. This applies to later-described fourth, seventh and tenth preferred embodiments as well.

### Second Preferred Embodiment

A current-reuse-type frequency doubler having an input formed in a differential manner was described in the first preferred embodiment. Described in a second preferred embodiment is a current-reuse-type frequency doubler having both an input and an output formed in a differential manner.

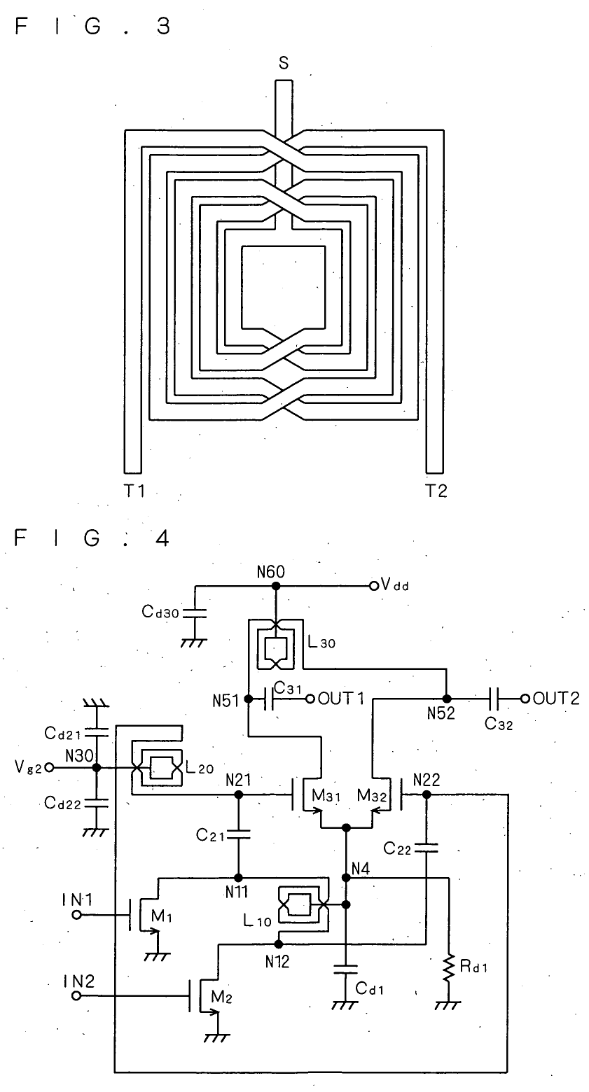

FIG. 2 is a circuit diagram illustrating the structure of a current-reuse-type frequency doubler according to the second preferred embodiment of this invention. As shown, this current-reuse-type frequency doubler includes differential input terminals IN1 and IN2, differential output terminals OUT1 and OUT2, N-channel MOS transistors M1, M₂, M₃₁ and M₃₂, capacitors C_{d1}, C_{d21}, C_{d22}, C_{d31}, C_{d32}; C₂₁, C₂₂, C₃₁ and C₃₂, inductors L₁₁, L₁₂, L₂₁, L₂₂, L₃, and L₃₂, and a resistance element R_{d1}. The inductors L₁₁, L₁₂, L₂₁, L₂₂, L₃₁ and L₃₂ are made of spiral inductors, for example.

Provided in the front stage of the current-reuse-type frequency doubler is a VCO (not shown) of differential operation having two differential output terminals. The differential input terminal IN1 is connected to one of the differential output terminals of the VCO, and the differential input terminal IN2 to the other differential output terminal of the VCO. RF signals in a complementary relationship with each other that are output from the VCO are input to the differential input terminals IN1 and IN2 as input signals.

The gate of the N-channel MOS transistor M₁ is connected to the differential input terminal IN1, and the gate of the N-channel MOS transistor M₂ to the differential input terminal IN2. The N-channel MOS transistors M₁ and M₂ each have a gate bias voltage being set near pinch-off voltage, which actually is set as a bias value between Class AB to Class B. The sources of the N-channel MOS transistors M₁ and M₂ are connected to a ground potential. More specifically, the sources of the N-channel MOS transistors M₁ and M₂ are commonly connected to a source pad (not shown) that is connected to a ground potential via ground wiring (not shown). The drain of the N-channel MOS transistor M₁ is connected to a node N11, and the drain of the N-channel MOS transistor M₂ to a node N12.

The capacitor C₂₁ is connected between the node N11 and a node N21, and a capacitor C₂₂ between the node N12 and a node N22. The inductor L₂₁ is connected between the node N21 and a node N31, and the inductor L₂₂ between the node N22 and a node N32. The capacitor C_{d21} is connected between the node N31 and a ground potential, and the capacitor C_{d22} between the node N32 and a ground potential. The inductor L₁₁ is connected between the nodes N11 and N4, and the inductor L₁₂ between the nodes N12 and N4. The capacitor C_{d1} is connected between the node N4 and a ground potential. The resistance element R_{d1} is connected between the node N4 and a ground potential.

The N-channel MOS transistor M₃₁ has a gate connected to the node N21, a source connected to the node N4, and a drain connected to a node N51. The N-channel MOS transistor M₃₂ has a gate connected to the node N22, a source connected to the node N4, and a drain connected to a node N52. The capacitor C₃₁ is connected between the node N51 and the differential output terminal OUT1, and the capacitor C₃₂ between the node N52 and the differential output terminal OUT2. The inductor L₃₁ is connected between the node N51 and a node N61, and the inductor L₃₂ between the node N52 and a node N62. The capacitor C_{d31} is connected between the node N61 and a ground potential, and the capacitor C_{d32} between the node N62 and a ground potential.

A gate bias voltage V_{g21} of the N-channel MOS transistor M₃₁ is applied to the node N31. A gate bias voltage V_{g22} of the N-channel MOS transistors M₃₂ is applied to the node N32: A power supply supplying a power supply voltage V_{dd} of 1.8 V or less is connected to the nodes N61 and N62.

The capacitors C_{d21}, C_{d22}, C_{d31} and C_{d32} act as decoupling capacitors. Namely, the capacitors C_{d21}, C_{d22}, C_{d31} and C_{d32} absorb noise (voltage fluctuations) on power supply wiring through the use of charge and discharge functions of capacitor.

Upon input of the RF signals in a complementary relationship with each other to the differential input terminals IN1 and IN2, a fundamental and a harmonic, primarily a double-wave, are output from the drain of each of the N-channel MOS transistors M₁ and M₂. In other words, the N-channel MOS transistors M₁ and M₂ act as a harmonic-generating circuit for generating a harmonic including a plurality of frequency components on the basis of the RF signals in a complementary relationship with each other.

The capacitances of the capacitors C₂, and C₂₂ and the inductances of the inductors L₂, and L₂₂ are set to match a double-wave. Consequently, a double-wave is extracted out of the fundamental and the harmonic including a plurality of frequency components that appear at the nodes N11 and N12, respectively, and transmitted to the gates of the N-channel MOS transistor M₃₁ and M₃₂, respectively. In other words, the capacitors C₂₁, C22 and inductors L₂₁, L₂₂ act as a harmonic-extracting circuit for extracting a harmonic (double-wave in this case) of a specific frequency component out of the fundamental and the harmonic generated by the N-channel MOS transistors M₁ and M₂.

The capacitances of the capacitors C₃, and C₃₂ and the inductances of the inductors L₃₁ and L₃₂ are set to match a double-wave. Thus, the double-wave having been transmitted to the gate of the N-channel MOS transistor M₃₁ is amplified by the N-channel MOS transistor M₃₁, and then output from the differential output terminal OUT1 via the capacitor C₃₁. Likewise, the double-wave having been transmitted to the gate of the N-channel MOS transistor M₃₂ is amplified by the N-channel MOS transistor M₃₂, and then output from the differential output terminal OUT2 via the capacitor C₃₂.

The capacitance of the capacitor C_{d1} and the inductances of the inductors L₁₁ and L₁₂ are set to match a fundamental. Consequently, the fundamental that appears at the node N11 is shorted to a ground potential via the inductor L₁₁ and capacitor C_{d1}, to be eliminated. Likewise, the fundamental that appears at the node N12 is shorted to a ground potential via the inductor L12 and capacitor C_{d1}, to be eliminated. In other words, the capacitor C_{d1} and inductors L₁₁, L₁₂ act as a fundamental-eliminating circuit (fundamental trap) for eliminating the fundamentals that appear at the nodes N11 and N12.

A direct current supplied from the power supply supplying the power supply voltage V_{dd} flows through the node N61, inductor L₃₁, node N51, N-channel MOS transistor M₃₁, node N4, inductor L₁₁ and node N11 in this order, into the N-channel MOS transistor M₁. A direct current supplied from the power supply supplying the power supply voltage V_{dd} also flows through the node N62, inductor L₃₂, node N52, N-channel MOS transistor M₃₂, node N4, inductor L₁₂ and node N12 in this order, into the N-channel MOS transistor M₂. In short, the currents flowing through the N-channel MOS transistors M₃₁ and M₃₂ are reused for operation of the N-channel MOS transistors M₁ and M₂, thus reducing power consumption.

In addition, part of the direct currents flows from the node N4 to a ground potential via the resistance element R_{d1}, the amount of the current being controllable in accordance with the resistance value of the resistance element R_{d1}. Stated another way, the amounts of current flowing from the N-channel MOS transistors M3, and M₃₂ into the N-channel MOS transistors M₁ and M₂ can be controlled by the resistance value of the resistance element R_{d1}. That allows amplifying operations of the N-channel MOS transistor M₃₁ and M₃₂ to be performed with stability even with small operating currents of the N-channel MOS transistors M₁ and M₂. That also prevents amplifying operations of the N-channel MOS transistor M₃₁ and M₃₂ from reaching saturation even when the output currents of the N-channel MOS transistors M₁ and M₂ increase.

The current-reuse-type frequency doubler according to the second preferred embodiment produces the following effect in addition to the effects obtainable with the current-reuse-type frequency doubler according to the first preferred embodiment. That is, since the current-reuse-type frequency doubler according to the second preferred embodiment includes the two differential output terminals OUT1 and OUT2, an arbitrary circuit (differential power amplifier, for example) of differential operation having two differential input terminals can be provided in a subsequent stage of this doubler. That allows the effect of the inductance of the ground wiring to be reduced or prevented in the operation of the circuit connected in the subsequent stage.

While the N-channel MOS transistors M₁, M₂, M₃₁ and M₃₂ are used in the current-reuse-type frequency doubler according to the second preferred embodiment, bipolar transistors or GaAs MESFETs may alternatively be used instead of those N-channel MOS transistors. This applies to later-described third, fifth, sixth, eighth, ninth, eleventh and twelfth preferred embodiments as well.

### Third Preferred Embodiment

FIG. 3 is a top view schematically illustrating the structure of a differential inductor. The differential inductor is a combination of a first spiral inductor having a terminal S as one end and a terminal T1 as a first other end, and a second spiral inductor having the terminal S as one end and a terminal T2 as a second other end, both of which are formed in the same region by using a plurality of wiring layers of multilevel wiring structure.

In a third preferred embodiment, the differential inductor is used to form the current-reuse-type frequency doubler according to the second preferred embodiment.

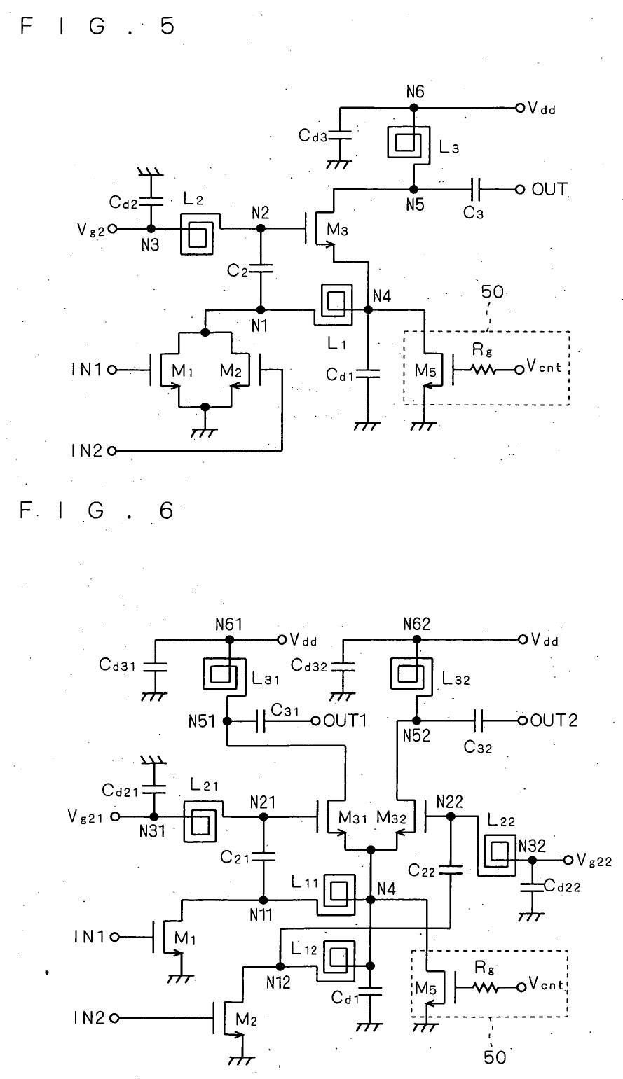

FIG. 4 is a circuit diagram illustrating the structure of a current-reuse-type frequency doubler according to the third preferred embodiment of this invention. As shown, this current-reuse-type frequency doubler includes differential input terminals IN1 and IN2, differential output terminals OUT1 and OUT2, N-channel MOS transistors M₁, M₂, M₃₁ and M₃₂, capacitors C_{d1}, C_{d21}, C_{d22}, C_{d30}, C₂₁, C₂₂, C₃₀, and C₃₂, differential inductors L₁₀, L₂₀ and L₃₀, and a resistance element R_{d1}.

The differential inductor L₂₀ corresponding to the inductors L₂, and L₂₂ illustrated in FIG. 2 is connected between a node N30 and nodes N21, N22. More specifically, the differential inductor L₂₀ has one end connected to the node N30, a first other end to the node N21, and a second other end to the node N22, respectively. The capacitor C_{d21} is connected between the node N30 and a ground potential, and the capacitor C_{d22} between the node N30 and a ground potential.

The differential inductor L₁₀ corresponding to the inductors L₁₁ and L₁₂ illustrated in FIG. 2 is connected between a node N4 and nodes N11, N12. More specifically, the differential inductor L₁₀ has one end connected to the node N4, a first other end to the node N11, and a second other end to the node N12, respectively.

The differential inductor L₃₀ corresponding to the inductors L₃₁ and L₃₂ illustrated in FIG. 2 is connected between a node N60 and nodes N51, N52. More specifically, the differential inductor L₃₀ has one end connected to the node N60, a first other end to the node N51, and a second other end to the node N52, respectively. The capacitor C_{d30} is connected between the node N60 and a ground potential.

A gate bias voltage V_{g2} of the N-channel MOS transistors M₃₁ and M₃₂ is applied to the node N30. A power supply supplying a power supply voltage V_{dd} of 1.8 V or less is connected to the node N60. The capacitor C_{d30} acts as a decoupling capacitor. Namely, the capacitor C_{d30} absorbs noise (voltage fluctuations) on power supply wiring through the use of charge and discharge functions of capacitor.

The other constituent elements of the current-reuse-type frequency doubler according to the third preferred embodiment are the same as the current-reuse-type frequency doubler according to the second preferred embodiment.

The current-reuse-type frequency doubler according to the third preferred embodiment produces the following effect in addition to the effects obtainable with the current-reuse-type frequency doubler according to the second preferred embodiment. That is, in the current-reuse-type frequency doubler according to the third preferred embodiment, the inductors L_{11 and L}₁₂ according to the second preferred embodiment are replaced with the common differential inductor L₁₀, the inductors L₂₁ and L₂₂ with the common differential inductor L₂₀, and the inductors L₃₁ and L₃₂ with the common differential inductor L₃₀. Therefore, the layout area necessary for forming the inductors can be reduced almost by half as compared with the current-reuse-type frequency doubler according to the second preferred embodiment, thereby shrinking the size of the device.

### Fourth Preferred Embodiment

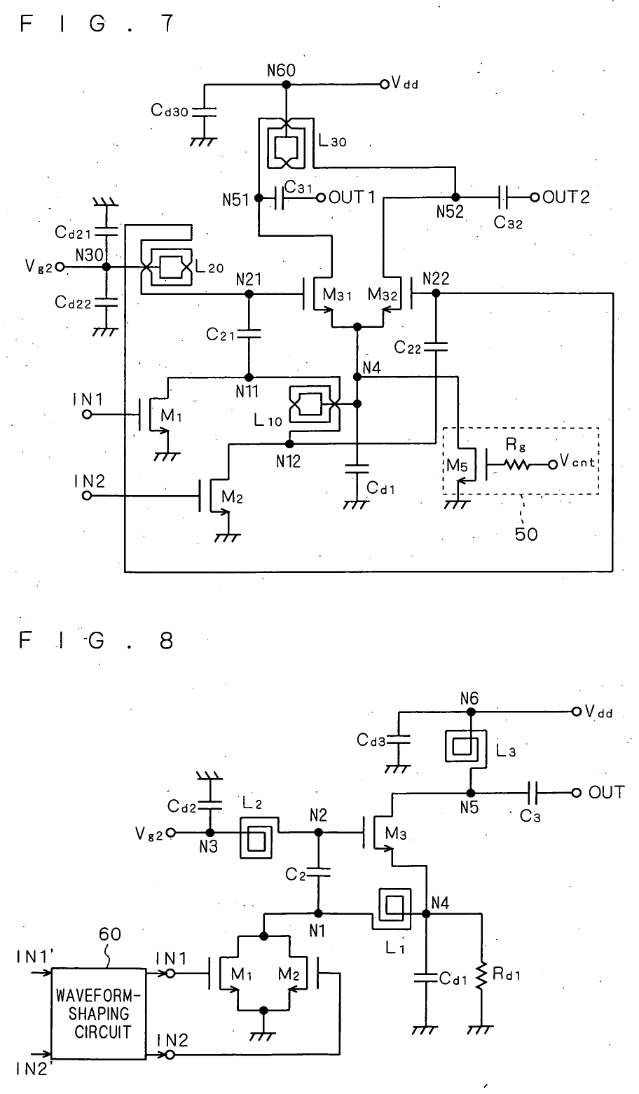

FIG. 5 is a circuit diagram illustrating the structure of a current-reuse-type frequency doubler according to a fourth preferred embodiment of this invention. On the basis of the current-reuse-type frequency doubler according to the first preferred embodiment illustrated in FIG. 1, a current-adjusting circuit 50 including an N-channel MOS transistor M₅ and a resistance element R_{g} is provided instead of the resistance element R_{d1} having a constant resistance value. The other constituent elements of the current-reuse-type frequency doubler according to the fourth preferred embodiment are the same as the current-reuse-type frequency doubler according to the first preferred embodiment.

The N-channel MOS transistor M₅ has a gate connected to the resistance element R_{g}, a source connected to a ground potential, and a drain connected to the node N4. A gate control voltage V_{cnt} having a variable voltage value is applied to the gate of the N-channel MOS transistor M₅ via the resistance element R_{g}. A drain current of the N-channel MOS transistor M₅ can be adjusted in accordance with the voltage value of the gate control voltage V_{cnt}. In other words, the current-adjusting circuit 50 acts as a variable resistance element.

The current-reuse-type frequency doubler according to the fourth preferred embodiment produces the following effect in addition to the effects obtainable with the current-reuse-type frequency doubler according to the first preferred embodiment. That is, in the current-reuse-type frequency doubler according to the fourth preferred embodiment, the drain current of the N-channel MOS transistor M₅ can be adjusted in accordance with the voltage value of the gate control voltage V_{cnt}. Therefore, the amount of current flowing from the N-channel MOS transistor M₃ to the N-channel MOS transistors M₁ and M₂ can be controlled in accordance with the voltage value of the gate control voltage V_{cnt}. This allows the value of input power to be set such that maximum conversion gain is obtained in agreement with an optimum level diagram of each system.

While the N-channel MOS transistor M₅ is used in the current-reuse-type frequency doubler according to the fourth preferred embodiment, a bipolar transistor or a GaAs MESFET may alternatively be used instead of that N-channel MOS transistor. This applies to later-described fifth, sixth, and tenth to twelfth preferred embodiments as well.

### Fifth Preferred Embodiment

FIG. 6 is a circuit diagram illustrating the structure of a current-reuse-type frequency doubler according to a fifth preferred embodiment of this invention. On the basis of the current-reuse-type frequency doubler according to the second preferred embodiment illustrated in FIG. 2, the same current-adjusting circuit 50 as the fourth preferred embodiment is provided instead of the resistance element R_{d1} having a constant resistance value. The other constituent elements of the current-reuse-type frequency doubler according to the fifth preferred embodiment are the same as the current-reuse-type frequency doubler according to the second preferred embodiment.

The current-reuse-type frequency doubler according to the fifth preferred embodiment produces the following effect in addition to the effects obtainable with the current-reuse-type frequency doubler according to the second preferred embodiment. That is, in the current-reuse-type frequency doubler according to the fifth preferred embodiment, the value of input power can be set such that maximum conversion gain is obtained in agreement with an optimum level diagram of each system, as in the fourth preferred embodiment.

### Sixth Preferred Embodiment

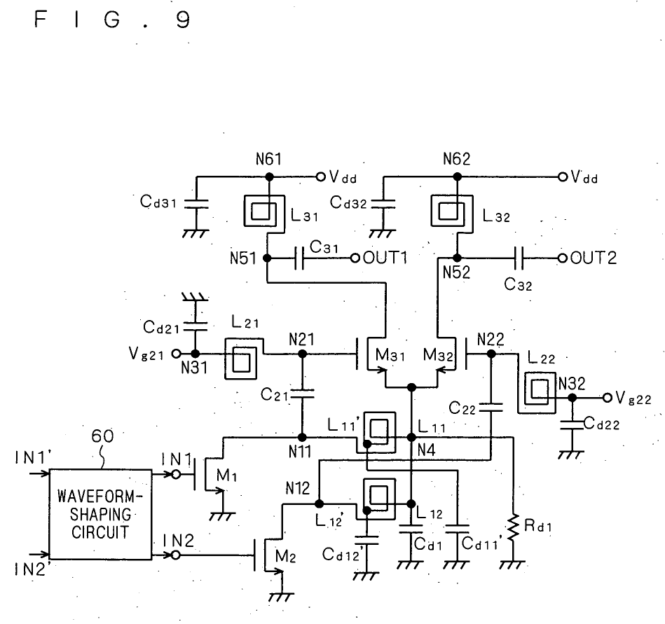

FIG. 7 is a circuit diagram illustrating the structure of a current-reuse-type frequency doubler according to a sixth preferred embodiment of this invention. On the basis of the current-reuse-type frequency doubler according to the third preferred embodiment illustrated in FIG. 4, the same current-adjusting circuit 50 as the fourth preferred embodiment is provided instead of the resistance element R_{d1} having a constant resistance value. The other constituent elements of the current-reuse-type frequency doubler according to the sixth preferred embodiment are the same as the current-reuse-type frequency doubler according to the third preferred embodiment.

The current-reuse-type frequency doubler according to the sixth preferred embodiment produces the following effect in addition to the effects obtainable with the current-reuse-type frequency doubler according to the third preferred embodiment. That is, in the current-reuse-type frequency doubler according to the sixth preferred embodiment, the value of input power can be set such that maximum conversion gain is obtained in agreement with an optimum level diagram of each system, as in the fourth preferred embodiment.

### Seventh Preferred Embodiment

FIG. 8 is a circuit diagram illustrating the structure of a current-reuse-type frequency quadrupler according to a seventh preferred embodiment of this invention. On the basis of the current-reuse-type frequency doubler according to the first preferred embodiment illustrated in FIG. 1, a waveform-shaping circuit 60 of differential operation is connected between the VCO and the differential input terminals IN1 and IN2. The waveform-shaping circuit 60 is formed by inverter arrays and the like, and has the function of shaping an input sine wave into a rectangular wave and outputting the same. The two differential output terminals of the VCO are connected to two differential input terminals IN1′ and IN2′ of the waveform-shaping circuit 60, and two differential output terminals of the waveform-shaping circuit 60 are connected to the differential input terminals IN1 and IN2.

The waveform-shaping circuit 60 receives the RF signals in a complementary relationship with each other from the VCO, reshapes the RF signals into rectangular waves, and outputs the same. In the course of reshaping into rectangular waves, harmonic components included in the input RF signals increase. The RF signals having increased harmonic components are input to the differential input terminals IN1 and IN2 as input signals. In other words, the waveform-shaping circuit 60 acts as an input circuit for increasing the harmonic components included in the RF signals and inputting them to the N-channel MOS transistors M₁ and M₂.

Upon input of the RF signals having harmonic components increased beforehand to the differential input terminals IN1 and IN2, a harmonic component increases in an even-ordered harmonic output from the common drain of the N-channel MOS transistors M₁ and M₂ as well. Meanwhile, the input of the RF signals in a complementary relationship with each other to the differential input terminals IN1 and IN2 causes a fundamental and an odd-ordered harmonic to cancel each other out, as described in the first preferred embodiment.

Accordingly, in the current-reuse-type frequency quadrupler according to the seventh preferred embodiment, the capacitance of the capacitor C₂ and the inductance of the inductor L₂ are set to match a quadri-wave. Consequently, a quadri-wave is extracted out of the harmonic including a plurality of frequency components that appears at the node N1, and transmitted to the gate of the N-channel MOS transistor M₃.

The capacitance of the capacitor C₃ and the inductance of the inductor L₃ are set to match a quadri-wave as well. Thus, the quadri-wave having been transmitted to the gate of the N-channel MOS transistor M₃ is amplified by the N-channel MOS transistor M₃, and then output from the output terminal OUT via the capacitor C₃.

The capacitance of the capacitor C_{d1} and the inductance of the inductor L₁ are set to match a double-wave. Consequently, the double-wave that appears at the node N1 is shorted to a ground potential via the inductor L₁ and capacitor C_{d1}, to be eliminated. In other words, the capacitor C_{d1} and inductor L₁ act as a harmonic-eliminating circuit (double-wave trap) for eliminating the double-wave that appears at the node N1.

The other constituent elements of the current-reuse-type frequency quadrupler according to the seventh preferred embodiment are the same as the current-reuse-type frequency doubler according to the first preferred embodiment.

The current-reuse-type frequency quadrupler according to the seventh preferred embodiment produces the following effect in addition to the effects obtainable with the current-reuse-type frequency doubler according to the first preferred embodiment. That is, a current-reuse-type frequency quadrupler can be obtained simply by connecting the waveform-shaping circuit 60 between the VCO and the differential input terminals IN1 and IN2 on the basis of the current-reuse-type frequency doubler according to the first preferred embodiment.

### Eighth Preferred Embodiment

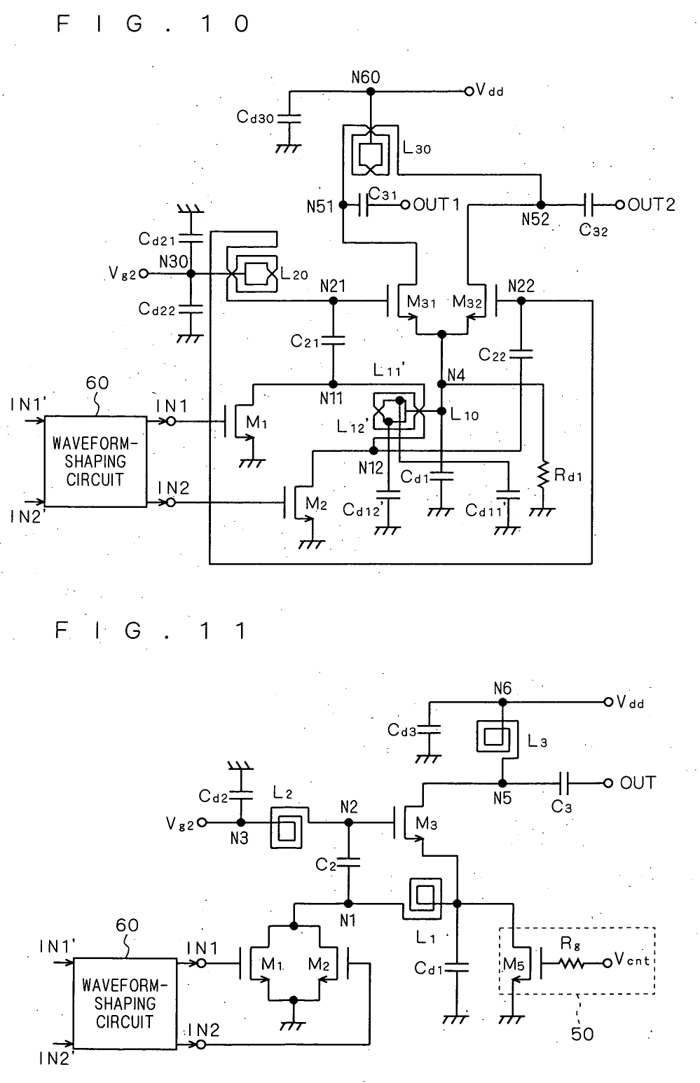

FIG. 9 is a circuit diagram illustrating the structure of a current-reuse-type frequency tripler according to an eighth preferred embodiment of this invention. On the basis of the current-reuse-type frequency doubler according to the second preferred embodiment illustrated in FIG. 2, the same waveform-shaping circuit 60 as the seventh preferred embodiment is connected between the VCO and the differential input terminals IN1 and IN2.

An inductor L₁₁′, which is part of the inductor L₁₁, is connected to a ground potential via a capacitor C_{d11}′. Likewise, an inductor L₁₂′, which is part of the inductor L₁₂, is connected to a ground potential via a capacitor C_{d12}′.

Upon input of the RF signals having harmonic components increased beforehand to the differential input terminals IN1 and IN2, a harmonic component increases in a harmonic output from the common drain of the N-channel MOS transistors M₁ and M₂ as well.

Accordingly, in the current-reuse-type frequency tripler according to the eighth preferred embodiment, the capacitances of the capacitor C₂₁ and C₂₂ and the inductances of the inductors L₂₁ and L₂₂ are set to match a triple-wave. Consequently, a triple-wave is extracted out of the harmonic including a plurality of frequency components that appears at the node N11, and transmitted to the gate of the N-channel MOS transistor M₃₁, while a triple-wave is extracted out of the harmonic including a plurality of frequency components that appears at the node N12, and transmitted to the gate of the N-channel MOS transistor M₃₂.

The capacitances of the capacitors C₃₁ and C₃₂ and the inductances of the inductors L₃₁ and L₃₂ are set to match a triple-wave as well. Accordingly, the triple-wave having been transmitted to the gate of the N-channel MOS transistor M₃₁ is amplified by the N-channel MOS transistor M₃₁, and then output from the differential output terminal OUT1 via the capacitor C₃₁. Likewise, the triple-wave having been transmitted to the gate of the N-channel MOS transistor M₃₂ is amplified by the N-channel MOS transistor M₃₂, and then output from the differential output terminal OUT2 via the capacitor C₃₂.

The capacitance of the capacitor C_{d1} and the inductances of the inductors L₁₁ and L₁₂ are set to match a fundamental. Consequently, the fundamental that appears at the node N 11 is shorted to a ground potential via the inductor L₁₁ and capacitor C_{d1}, to be eliminated. Likewise, the fundamental that appears at the node N12 is shorted to a ground potential via the inductor L₁₂ and capacitor C_{d1}, to be eliminated. In other words, the capacitor C_{d1} and inductors L₁₁, L₁₂ act as a fundamental-eliminating circuit (fundamental trap) for eliminating the fundamentals that appear at the nodes N11 and N12.

The capacitances of the capacitors C_{d11}′ and C_{d12}′ and the inductances of the inductors L₁₁′ and L₁₂′ are set to match a double-wave. Consequently, the double-wave that appears at the node N11 is shorted to a ground potential via the inductor L₁₁′ and capacitor C_{d11}′, to be eliminated. Likewise, the double-wave that appears at the node N12 is shorted to a ground potential via the inductor L₁₂′ and capacitor C_{d12}′, to be eliminated. In other words, the capacitors C_{d11}′, C_{d12}′ and inductors L₁₁′, L₁₂′ act as a double-wave eliminating circuit (double-wave trap) for eliminating the double-waves that appear at the nodes N11 and N12.

The other constituent elements of the current-reuse-type frequency tripler according to the eighth preferred embodiment are the same as the current-reuse-type frequency doubler according to the second preferred embodiment.

The current-reuse-type frequency tripler according to the eighth preferred embodiment produces the following effect in addition to the effects obtainable with the current-reuse-type frequency doubler according to the second preferred embodiment. That is, a current-reuse-type frequency tripler can be obtained simply by connecting the waveform-shaping circuit 60 between the VCO and the differential input terminals IN1 and IN2 on the basis of the current-reuse-type frequency doubler according to the second preferred embodiment.

### Ninth Preferred Embodiment

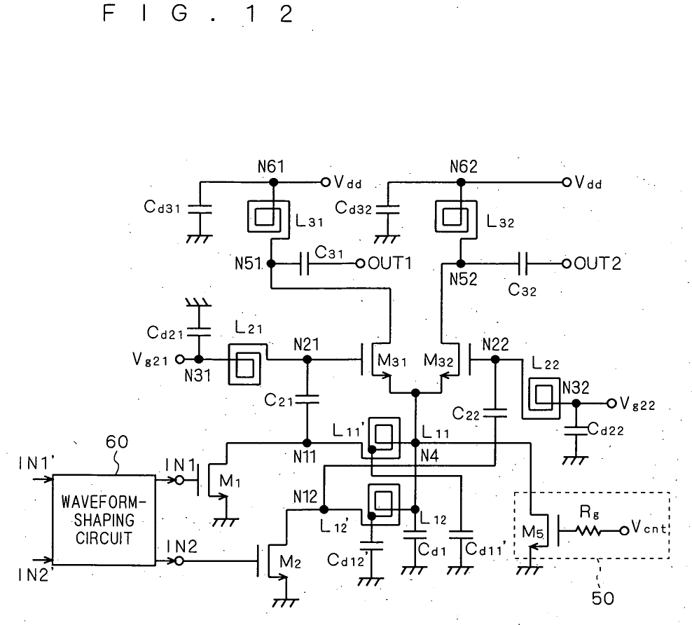

FIG. 10 is a circuit diagram illustrating the structure of a current-reuse-type frequency tripler according to a ninth preferred embodiment of this invention. On the basis of the current-reuse-type frequency doubler according to the third preferred embodiment illustrated in FIG. 4, the same waveform-shaping circuit 60 as the seventh preferred embodiment is connected between the VCO and the differential input terminals IN1 and IN2.

An inductor L₁₁′, which is part of the differential inductor L₁₀, is connected to a ground potential via a capacitor C_{d11}′. Likewise, an inductor L₁₂′, which is part of the differential inductor L₁₀, is connected to a ground potential via a capacitor C_{d12}′.

Upon input of the RF signals having harmonic components increased beforehand to the differential input terminals IN1 and IN2, a harmonic component increases in a harmonic output from the common drain of the N-channel MOS transistors M₁ and M₂ as well.

Accordingly, in the current-reuse-type frequency tripler according to the ninth preferred embodiment, the capacitances of the capacitors C₂, and C₂₂ and the inductance of the differential inductor L₂₀ are set to match a triple-wave. Consequently, a triple-wave is extracted out of the harmonic including a plurality of frequency components that appears at the node N11, and transmitted to the gate of the N-channel MOS transistor M₃₁, while a triple-wave is extracted out of the harmonic including a plurality of frequency components that appears at the node N12, and transmitted to the gate of the N-channel MOS transistor M₃₂.

The capacitances of the capacitors C₃₁ and C₃₂ and the inductance of the differential inductor L₃₀ are set to match a triple-wave as well. Thus, the triple-wave having been transmitted to the gate of the N-channel MOS transistor M₃₁ is amplified by the N-channel MOS transistor M₃₁, and then output from the differential output terminal OUT1 via the capacitor C₃₁. Likewise, the triple-wave having been transmitted to the gate of the N-channel MOS transistor M₃₂ is amplified by the N-channel MOS transistor M₃₂, and then output from the differential output terminal OUT2 via the capacitor C₃₂.

The capacitance of the capacitor C_{d1} and the inductance of the differential inductor L₁₀ are set to match a fundamental. Consequently, the fundamentals that appear at the nodes N11 and N12 are shorted to a ground potential via the differential inductor L₁₀ and capacitor C_{d1}, to be eliminated. In other words, the capacitor C_{d1} and differential inductor L₁₀ act as a fundamental-eliminating circuit (fundamental trap) for eliminating the fundamentals that appear at the node N11 and N 2.

The capacitances of the capacitors C_{d11}′ and C_{d12}′ and the inductances of the inductors L₁₁′ and L₁₂′ are set to match a double-wave. Consequently, the double-wave that appears at the node N11 is shorted to a ground potential via the inductor L₁₁′ and capacitor C_{d11}′, to be eliminated. Likewise, the double-wave that appears at the node N12 is shorted to a ground potential via the inductor L₁₂′ and capacitor C_{d12}′, to be eliminated. In other words, the capacitors C_{d11}′, C_{d12}′ and inductors L₁₁′, L₁₂′ act as a double-wave eliminating circuit (double-wave trap) for eliminating the double-waves that appear at the nodes N11 and N12.

The other constituent elements of the current-reuse-type frequency tripler according to the ninth preferred embodiment are the same as the current-reuse-type frequency doubler according to the third preferred embodiment.

The current-reuse-type frequency tripler according to the ninth preferred embodiment produces the following effect in addition to the effects obtainable with the current-reuse-type frequency doubler according to the third preferred embodiment. That is, a current-reuse-type frequency tripler can be obtained simply by connecting the waveform-shaping circuit 60 between the VCO and the differential input terminals IN1 and IN2 on the basis of the current-reuse-type frequency doubler according to the third preferred embodiment.

### Tenth Preferred Embodiment

FIG. 11 is a circuit diagram illustrating the structure of a current-reuse-type frequency quadrupler according to a tenth preferred embodiment of this invention. On the basis of the current-reuse-type frequency quadrupler according to the seventh preferred embodiment illustrated in FIG. 8, the same current-adjusting circuit 50 as the fourth preferred embodiment is provided instead of the resistance element R_{d1} having a constant resistance value. The other constituent elements of the current-reuse-type frequency quadrupler according to the tenth preferred embodiment are the same as the current-reuse-type frequency quadrupler according to the seventh preferred embodiment.

The current-reuse-type frequency quadrupler according to the tenth preferred embodiment produces the following effect in addition to the effects obtainable with the current-reuse-type frequency quadrupler according to the seventh preferred embodiment. That is, in the current-reuse-type frequency quadrupler according to the tenth preferred embodiment, the value of input power can be set such that maximum conversion gain is obtained in agreement with an optimum level diagram of each system, as in the fourth preferred embodiment.

### Eleventh Preferred Embodiment

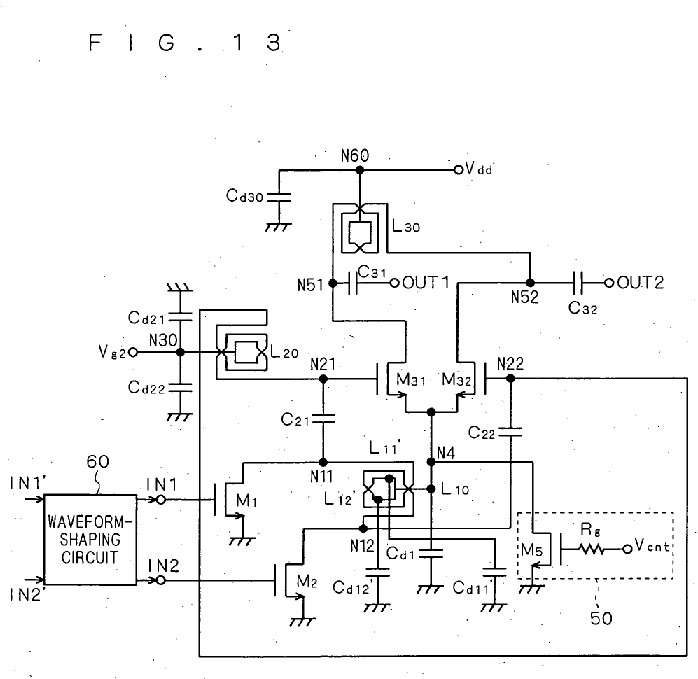

FIG. 12 is a circuit diagram illustrating the structure of a current-reuse-type frequency tripler according to an eleventh preferred embodiment of this invention. On the basis of the current-reuse-type frequency tripler according to the eighth preferred embodiment illustrated in FIG. 9, the same current-adjusting circuit 50 as the fourth preferred embodiment is provided instead of the resistance element R_{d1} having a constant resistance value. The other constituent elements of the current-reuse-type frequency tripler according to the eleventh preferred embodiment are the same as the current-reuse-type frequency tripler according to the eighth preferred embodiment.

The current-reuse-type frequency tripler according to the eleventh preferred embodiment produces the following effect in addition to the effects obtainable with the current-reuse-type frequency tripler according to the eighth preferred embodiment. That is, in the current-reuse-type frequency tripler according to the eleventh preferred embodiment, the value of input power can be set such that maximum conversion gain is obtained in agreement with an optimum level diagram of each system, as in the fourth preferred embodiment.

### Twelfth Preferred Embodiment

FIG. 13 is a circuit diagram illustrating the structure of a current-reuse-type frequency tripler according to a twelfth preferred embodiment of this invention. On the basis of the current-reuse-type frequency tripler according to the ninth preferred embodiment illustrated in FIG. 10, the same current-adjusting circuit 50 as the fourth preferred embodiment is provided instead of the resistance element R_{d1} having a constant resistance value. The other constituent elements of the current-reuse-type frequency tripler according to the twelfth preferred embodiment are the same as the current-reuse-type frequency tripler according to the ninth preferred embodiment.

The current-reuse-type frequency tripler according to the twelfth preferred embodiment produces the following effect in addition to the effects obtainable with the current-reuse-type frequency tripler according to the ninth preferred embodiment. That is, in the current-reuse-type frequency tripler according to the twelfth preferred embodiment, the value of input power can be set such that maximum conversion gain is obtained in agreement with an optimum level diagram of each system, as in the fourth preferred embodiment.

While the invention has been shown and described in detail, the foregoing description is in all aspects illustrative and not restrictive. It is therefore understood that numerous modifications and variations can be devised without departing from the scope of the invention.

What is claimed is:

1. A current-reuse-type frequency multiplier comprising:
a harmonic-generating circuit generating a harmonic including a plurality of frequency components on the basis of first and second input signals in a complementary relationship with each other;
a harmonic-extracting circuit extracting a harmonic of a specific frequency component out of said harmonic generated by said harmonic-generating circuit;
an amplifying circuit amplifying said harmonic extracted by said harmonic-extracting circuit to output the same; and
a resistance element controlling a current flowing from said amplifying circuit into said harmonic-generating circuit, wherein
said harmonic-generating circuit includes a first transistor and a second transistor, said first transistor having a gate to which said first input signal is input, and said second transistor having a gate to which said second input signal is input.

2. The current-reuse-type frequency multiplier according to claim 1, wherein
said harmonic-extracting circuit includes:
a first extracting circuit extracting said harmonic of said specific frequency component out of said harmonic including said plurality of frequency components output from said first transistor; and
a second extracting circuit extracting said harmonic of said specific frequency component out of said harmonic including said plurality of frequency components output from said second transistor, and
said amplifying circuit includes:
a third transistor having a gate to which said harmonic extracted by said first extracting circuit is input; and
a fourth transistor having a gate to which said harm onic extracted by said second extracting circuit is input.

3. The current-reuse-type frequency multiplier according to claim 2, wherein
said first extracting circuit includes:
a first capacitor connected between said first and third transistors; and
a first inductor connected to said first capacitor,
said second extracting circuit includes:
a second capacitor connected between said second and fourth transistors; and
a second inductor connected to said second capacitor, and
said first and second inductors are formed of a common differential inductor.

4. The current-reuse-type frequency multiplier according to claim 1, wherein said resistance element has a variable resistance value.

5. The current-reuse-type frequency multiplier according to claim 1, further comprising:
an input circuit amplifying harmonic components included in said first and second input signals to input the same to said harmonic-generating circuit, said input circuit being connected to an input of said harmonic-generating circuit; and
a harmonic-eliminating circuit eliminating a harmonic of relatively low frequency out of said harmonic generated by said harmonic-generating circuit, wherein
said harmonic-extracting circuit extracts a harmonic of relatively high frequency.
